(19) United States
(12) Patent Application Publication
(10) Pub. No.: US 2023/0354708 A1
(43) Pub. Date: Nov. 2, 2023

(54) THERMOELECTRIC MODULE

(71) Applicant: LG INNOTEK CO., LTD., Seoul (KR)

(72) Inventors: Sue Kyung OH, Seoul (KR); Myoung Lae ROH, Seoul (KR); Seung Yong LEE, Seoul (KR)

(21) Appl. No.: 18/041,417

(22) PCT Filed: Aug. 11, 2021
(86) PCT No.: PCT/KR2021/010645

§ 371 Date: Feb. 13, 2023

(30) Foreign Application Priority Data
Aug. 11, 2020 (KR) 10-2020-0100605

(51) Int. Cl. H10N 10/13; H10N 10/17

(52) U.S. Cl. CPC H10N 10/13; H10N 10/17

(57) ABSTRACT

Disclosed according to an embodiment is a thermoelectric module comprising: a first heat-conducting member including a first recess; a second heat-conducting member spaced apart from the first heat-conducting member; a thermoelectric element disposed between the first heat-conducting member and the second heat-conducting member; and a circuit unit electrically connected to the thermoelectric element to control resistance, wherein the circuit unit is disposed in the first recess.

### TECHNICAL FIELD

The present invention relates to a thermoelectric element, and more specifically, to a thermoelectric module using a temperature difference between a low-temperature portion and a high-temperature portion of a thermoelectric element or a Peltier device which cools or heats a specific object such as a fluid or the like.

### BACKGROUND ART

A thermoelectric phenomenon is a phenomenon which occurs due to the movement of electrons and holes in a material, and refers to direct energy conversion between heat and electricity.

A thermoelectric element is a generic term for an element using the thermoelectric phenomenon and has a structure in which a. P-type thermoelectric material and an N-type thermoelectric material are joined between metal electrodes to form a PN junction pair.

Thermoelectric elements can be classified into an element using temperature changes of electrical resistance, an element using the Seebeck effect, which is a phenomenon in which an electromotive force is generated due to a temperature difference, an element using the Peltier effect, which is a phenomenon in which heat absorption or heat generation by current occurs, and the like.

The thermoelectric element is variously applied to home appliances, electronic components, communication components, or the like. For example, the thermoelectric element can be applied to a cooling device, a heating device, a power generation device, or the like. Accordingly, the demand for thermoelectric performance of the thermoelectric element is increasing more and more.

When the thermoelectric element is applied to a device for power generation, it is possible to allow a first fluid to flow to a low-temperature portion side of the thermoelectric element, and allow a second fluid having a higher temperature than the first fluid to flow to a high-temperature portion side of the thermoelectric element. Accordingly, electricity can be generated due to a temperature difference between the low-temperature portion and the high-temperature portion of the thermoelectric element.

### DISCLOSURE

### Technical Problem

The present invention is directed to providing a thermoelectric module using a temperature difference between a low-temperature portion and a high-temperature portion of a thermoelectric element or a power generation device which cools or heats a specific object such as a fluid or the like.

Specifically, the present invention is directed to providing a thermoelectric module which has a recess, in which a circuit unit may be disposed at a low-temperature portion side, and thus reduces an electrical distance between the circuit unit and a thermoelectric element to improve power generation performance and prevent reliability of the circuit unit from being lowered by heat, or a power generation device.

### Technical Solution

A thermoelectric module according to an embodiment of the present invention includes: a first heat-conducting member including a first pipe through which a first fluid moves and a first recess; a second heat-conducting member including a second pipe through which a second fluid having a higher temperature than the first fluid moves; a thermoelectric element disposed between the first heat-conducting member and the second heat-conducting member; and a circuit unit electrically connected to the thermoelectric element, wherein the circuit unit is disposed in the first recess.

The first heat-conducting member may further include a wire hole passing through from an outer surface of the first heat-conducting member to the first recess.

The thermoelectric module may further include a connection line electrically connected to the circuit unit and disposed in the wire hole.

The thermoelectric module may further include a sealing member surrounding the thermoelectric element between the first heat-conducting member and the second heat-conducting member.

The sealing member may surround the first recess and the circuit unit.

The first heat-conducting member may include a first inlet and a first outlet, the second heat-conducting member may include a second inlet and a second outlet, the first inlet and the second inlet may be positioned to correspond to each other, and the first outlet and the second outlet may be positioned to correspond to each other.

The first pipe may at least partially overlap the thermoelectric element, and the second pipe may at least partially overlap the thermoelectric element.

The thermoelectric element may include a first substrate configured to conic into contact with the first heat-conducting member and a second substrate configured to come into contact with the second heat-conducting member.

The first substrate may include a first region overlapping the second substrate and a second region outside the second substrate.

The second region may include a coupling hole coupled to the first heat-conducting member, and the thermoelectric module may further include a coupling member passing through the coupling hole.

A bonding member may be further disposed between the second substrate and the second heat-conducting member.

The first heat-conducting member may include a first surface facing the second heat-conducting member, the second heat-conducting member may include a second surface facing the first surface, the first surface may include a first edge groove disposed along an edge thereof, and the second surface may include a second edge groove disposed along an edge thereof.

The first edge groove and the second edge groove may overlap in a vertical direction, and the sealing member may be disposed between the first edge groove and the second edge groove.

### Advantageous Effects

According to an embodiment of the present invention, a power generation device having a thermoelectric module which can be simply assembled and has excellent power generation performance according to temperature difference improvement can be acquired.

Further, according to the embodiment of the present invention, a thermoelectric module having improved reliability can be provided.

Specifically, according to the embodiment of the present invention, a process of disposing a shield member on the thermoelectric module is simple, and the thermoelectric module can be protected from moisture, heat, or other contaminants.

Further, the thermoelectric element or thermoelectric module according to the embodiment of the present invention can be applied not only to an application implemented in a small size but also to an application implemented in a large size such as a waste heat pipe such as a heat transport pipe, a rainwater pipe, or an oil pipeline, a vehicle, a ship, a steel mill, an incinerator, or the like.

### DESCRIPTION OF DRAWINGS

FIG. 1 is a perspective view of a thermoelectric module according to an embodiment of the present invention.

FIG. 2 is an exploded perspective view of the thermoelectric module according to the embodiment of the present invention.

FIGS. 3A and 3B are views of a first heat-conducting member and a second heat-conducting member of the thermoelectric module according to the embodiment of the present invention.

FIG. 4 is a cross-sectional view of a thermoelectric element included in the thermoelectric module according to the embodiment of the present invention.

FIG. 5 is a conceptual diagram of the thermoelectric element included in the thermoelectric module according to the embodiment of the present invention.

FIG. 6 is an exploded perspective view of the thermoelectric element according to the embodiment of the present invention.

FIG. 7 is a view in which the second heat-conducting member is removed from the thermoelectric module according to the embodiment of the present invention.

FIG. 8 is an enlarged view of portion K in FIG. 7.

FIG. 9 is a cross-sectional view taken along line I-I′ in FIG. 8.

FIG. 10 is a cross-sectional view taken along line in FIG. 1.

FIG. 11 is an enlarged view of portion Lin FIG. 7.

FIG. 12 is a side view of the thermoelectric module according to the embodiment.

FIG. 13 is another side view of the thermoelectric module according to the embodiment.

FIG. 14 is a cross-sectional view taken along line M-M′ in FIG. 11.

### MODES OF THE INVENTION

Hereinafter, preferable embodiments of the present invention will be described in detail with reference to the accompanying drawings.

However, the technical spirit of the present invention is not limited to some embodiments which will be described and may be embodied in various forms, and one or more elements in the embodiments may be selectively combined and replaced to be used within the scope of the technical spirit of the present invention.

Further, terms used in the embodiments of the present invention (including technical and scientific terms), may be interpreted with meanings that are generally understood by those skilled in the art unless particularly defined and described, and terms which are generally used, such as terms defined in a dictionary, may be understood in consideration of their contextual meanings in the related art.

In addition, terms used in the description are provided not to limit the present invention but to describe the embodiments.

In the specification, the singular form may also include the plural form unless the context clearly indicates otherwise and may include one or more of all possible combinations of A, B, and C when disclosed as at least one (or one or more) of “A, B, and C.”

In addition, terms such as first, second, A, B, (a), (b), and the like may be used to describe elements of the embodiments of the present invention.

Such terms are only provided to distinguish the elements from other elements, and the essence, sequence, order, or the like of the elements are not limited by the terms.

Further, when particular elements are disclosed as being “connected,” “coupled,” or “linked” to other elements, the elements may include not only a case of being directly connected, coupled, or linked to other elements but also a case of being connected, coupled, or linked to other elements by elements between the elements and other elements.

In addition, when one element is disclosed as being formed “on or under” another element, the term “on or under” includes both a case in which the two elements are in direct contact with each other and a case in which at least another element is disposed between the two elements (indirect contact). Further, when the term “on or under” is expressed, a meaning of not only an upward direction but also a downward direction may be included based on one element.

First, a thermoelectric device (or a thermoelectric module) of the present invention may be used in a power generation device, a power generation system formed of the power generation device, or the like. For example, the power generation system includes a power generation device (including a thermoelectric module or a thermoelectric element) and fluid pipes, and a fluid introduced into the fluid pipes may be a heat source generated from a waste heat pipe such as a heat transport pipe, a rainwater pipe, an oil pipeline, or the like, an engine of an automobile, a ship, or the like, a power plant, a steel mill, or the like. However, the present invention is not limited to the above. The fluid pipes may include a first fluid pipe (hereinafter, referred to as a first pipe) and a second fluid pipe (hereinafter, referred to as a second pipe) through which a fluid having a higher temperature than a fluid flowing through the first fluid pipe flows, and the thermoelectric module may be disposed between the first fluid pipe and the second fluid pipe. For example, the temperature of the fluid flowing in the first fluid pipe may be 80° C. or less, preferably 60° C. or less, and more preferably 50° C., and the temperature of the fluid flowing in the second fluid pipe may be 100° C. or more, preferably 200° C. or more, and more preferably, 220° C. to 250° C., but are not limited thereto, and may be variously applied according to a temperature difference between a low-temperature portion and a high-temperature portion of the thermoelectric element. Further, the power generation device may be disposed adjacent to the fluid pipes to generate power using the energy of the fluid.

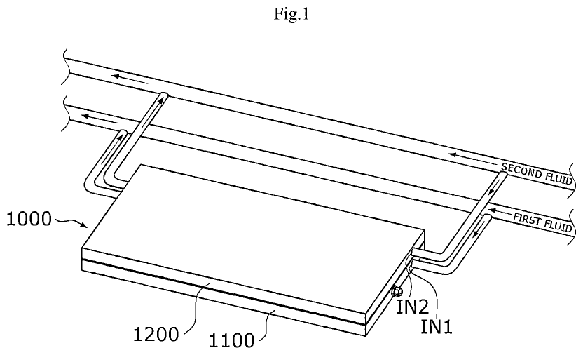

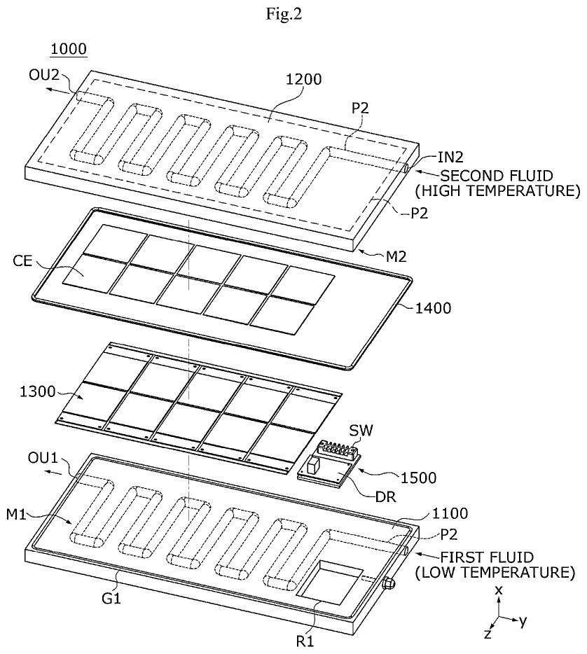

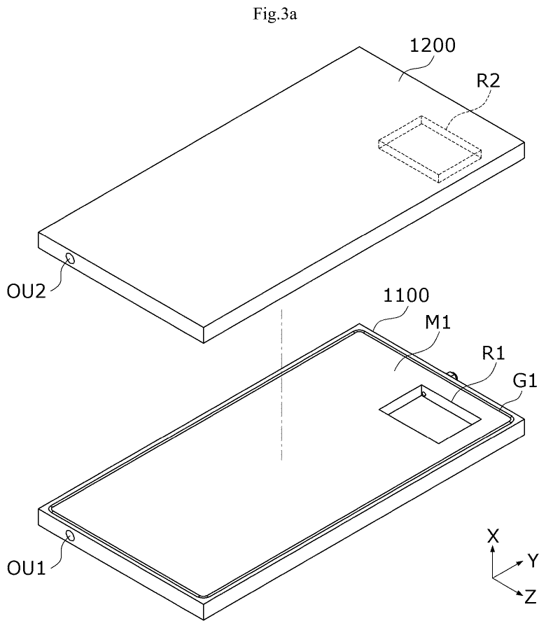

FIG. 1 is a perspective view of a thermoelectric module according to an embodiment of the present invention, FIG. 2 is an exploded perspective view of the thermoelectric module according to the embodiment of the present invention, and FIGS. 3A and 3B are views of a first heat-conducting member and a second heat-conducting member of the thermoelectric module according to the embodiment of the present invention.

Referring to FIGS. 1 and 2, a thermoelectric module 1000 according to the embodiment of the present invention may include a first heat-conducting member 1100, a second heat-conducting member 1200, a thermoelectric element 1300, a sealing member 1400, and a circuit unit 1500.

Furthermore, the thermoelectric module 1000 according to the embodiment may further include a first pipe P1 positioned in the first heat-conducting member 1100 or connected to the first heat-conducting member 1100 and through which a first fluid moves, a second pipe P2 through which a second fluid having a temperature higher than a temperature of the first fluid moves and which is positioned in the second heat-conducting member 1200 or connected to the second heat-conducting member 1200, and a bonding member CE disposed between the thermoelectric element 1300 and the second heat-conducting member 1200.

Specifically, the first pipe P1 and the second pipe P2 may be holes or pipes having spaces through which the first fluid and the second fluid may move, respectively. The first pipe P1 may be disposed in the first heat-conducting member 1100 and the second pipe P2 may be disposed in the second heat-conducting member 1200. In this case, each of the first pipe P1 and the second pipe P2 is connected to, for example, a heat transport pipe, and the first pipe P1 and the second pipe P2 are bypass-connected from the heat transport pipe so that a fluid may flow. For example, the first pipe P1 may be connected to a pipe bypassed in a low-temperature heat transport pipe. Accordingly, a low-temperature fluid may flow through the first pipe P1. Further, the second pipe P2 may be connected to a pipe bypassed from a relatively high-temperature heat transport pipe. Accordingly, a high-temperature fluid may flow through the second pipe P2.

Further, the first fluid may move in the first pipe P1 in a predetermined direction. In addition, the second fluid may move in the second pipe P2 in a predetermined direction. The first pipe P1 may receive heat from the first fluid, and the second pipe P2 may receive heat from the second fluid. Furthermore, since the temperature of the first fluid is lower than the temperature of the second fluid, the first heat-conducting member 1100 may be a low-temperature portion and the second heat-conducting member 1200 may be a high-temperature portion. Furthermore, a first substrate of the thermoelectric element adjacent to the first heat-conducting member 1100 and to which the heat is conducted from the first heat-conducting member 1100 may become the low-temperature portion, and a second substrate of the thermoelectric element adjacent to the second heat-conducting member 1200 and to which the heat is conducted from the second heat-conducting member 1200 may become the high-temperature portion. A description will be made based on this below.

The first pipe P1 and the second pipe P2 may be disposed to be spaced apart from each other in a first direction (an X-axis direction) like the first heat-conducting member 1100 and the second heat-conducting member 1200. Furthermore, the first pipe P1 and the second pipe P2 may be positioned to correspond to each other. In the present specification, the first direction (the X-axis direction) may be a direction from the first pipe P1 to the second pipe P2 or a direction from the first heat-conducting member 1100 to the second heat-conducting member 1200 to be described below. A second direction (a Y-axis direction) may be a direction perpendicular to the first direction (the X-axis direction) and may be a direction from first and second inlets to first and second outlets. Further, a third direction (a Z-axis direction) may be a direction perpendicular to the first direction (the X-axis direction) and the second direction (the Y-axis direction). Here, the X-axis direction, the Y-axis direction, and the Z-axis direction are shown to be perpendicular to each other, but are not limited thereto, and the X-axis direction, the Y-axis direction, and the Z-axis direction may have predetermined angles with each other.

As described above, the thermoelectric module 1000 may include the first heat-conducting member 1100 having the first pipe P1 through which the first fluid moves, the second heat-conducting member 1200 having the second pipe P2 through which the second fluid having a temperature higher than the temperature of the first fluid moves, the thermoelectric element 1300 which is disposed between the first heat-conducting member 1100 and the second heat-conducting member 1200 and comes into contact with the first heat-conducting member 1100 and the second heat-conducting member 1200, the sealing member 1400 surrounding the thermoelectric element 1300 between the first heat-conducting member 1100 and the second heat-conducting member 1200, and the circuit unit 1500 disposed in a first recess R1 of the first heat-conducting member 1100.

First, the first heat-conducting member 1100 may include the first pipe P1 and the first recess R1 formed therein. Further, the first heat-conducting member 1100 may be formed of a heat-conducting material. For example, the first heat-conducting member 1100 may include a metal, such as aluminum. Accordingly, the first heat-conducting member 1100 may receive heat from the first fluid flowing through the first pipe P1. In the first heat-conducting member 1100, the first pipe P1 may be positioned to at least partially overlap the thermoelectric element 1300 to be described below in the first direction. That is, in the first heat-conducting member 1100, the first pipe P1 may be positioned under a region which comes into contact with the thermoelectric element 1300.

Further, the first heat-conducting member 1100 may include a first inlet IN1 through which the first fluid is introduced into the first pipe P1 and a first outlet OU1. The first inlet IN1 and the first outlet OU1 may be positioned to correspond to each other in the second direction.

Further, in the first heat-conducting member 1100 according to the embodiment, the first recess R1 may be disposed to be spaced apart from the region which comes into contact with the thermoelectric element 1300. The circuit unit 1500 to be described below may be disposed in the first recess R1. According to this configuration, since the first heat-conducting member 1100 is in a low-temperature state due to the first fluid having a low temperature, even when heat is generated by driving of the circuit unit 1500, heat generation of the circuit unit 1500 may be suppressed by the first heat-conducting member 1100. Further, the first recess R1 may be positioned at the first inlet IN′ side. Accordingly, since the circuit unit 1500 in the first recess R1 is positioned adjacent to the low-temperature first fluid before heat is transferred to the thermoelectric element 1300 by the first fluid, cooling may be easily performed. Accordingly, since the resistance, capacity, and the like of the circuit element change in response to stress such as a high temperature, and consequent overcurrent and excessive power consumption are suppressed, the reliability of the circuit unit 1500 may be improved.

Furthermore, the first heat-conducting member 1100 may include a first edge groove G1. The first edge groove G1 may be positioned on a first surface M1 where the first heat-conducting member 1100 faces the second heat-conducting member 1200. The sealing member 1400 to be described below may be disposed in the first edge groove G1. Further, the first edge groove G1 may be disposed outside the thermoelectric element 1300 and the first recess R1. In an embodiment, the first edge groove G1 may be disposed along an edge of the first surface M1 of the first heat-conducting member 1100. Further, the first edge groove G1 may have a closed-loop shape in the YZ plane perpendicular to the first direction. Accordingly, through the sealing member 1400 disposed in the first edge groove G1, the thermoelectric element 1300, the circuit unit 1500, the first recess R1, and a second recess R2 may be surrounded by the sealing member 1400.

Accordingly, the thermoelectric element 1300 and the circuit unit 1500 may be shielded by the first heat-conducting member 1100 and the second heat-conducting member 1200 as well as the sealing member 1400. For example, the first heat-conducting member 1100 may be positioned under the thermoelectric element 1300, the second heat-conducting member 1200 may be positioned above the thermoelectric element 1400, and the sealing member 1400 may be positioned outside the thermoelectric element 1300. That is, the thermoelectric element 1300 may be positioned in an inner region formed by the first heat-conducting member 1100, the second heat-conducting member 1200, and the sealing member 1400. Accordingly, moisture resistance of the thermoelectric module according to the embodiment may be improved.

Further, the second heat-conducting member 1200 may include the second pipe P2 and the second recess R2 formed therein. Further, the second heat-conducting member 1200 may be made of a heat-conducting material like the first heat-conducting member 1100. For example, the second heat-conducting member 1200 may include a metal. For example, the second heat-conducting member 1200 may be formed of aluminum. Accordingly, the second heat-conducting member 1200 may receive heat from the second fluid flowing through the second pipe P2.

In the second heat-conducting member 1200, the second pipe P2 may be positioned to at least partially overlap the thermoelectric element 1300 in the first direction. Furthermore, the second pipe P2 may be positioned to correspond to the first pipe P1 of the first heat-conducting member 1100. That is, the second pipe P2 and the first pipe P1 may correspond to each other in a vertical direction. Accordingly, when a temperature difference at which the thermoelectric element may generate power is provided by the first fluid and the second fluid, a temperature difference between the first fluid in the first pipe P1 and the second fluid in the second pipe P2 may be maintained as much as possible to improve power generation efficiency. Further, in the second heat-conducting member 1200, the second pipe P2 may be positioned under the region which comes into contact with the thermoelectric element 1300.

Further, the second heat-conducting member 1200 may include a second inlet IN2 through which the second fluid is introduced into the second pipe P2 and a second outlet OU2. The second inlet IN2 and the second outlet OU2 may be positioned to correspond to each other in the second direction.

Further, the second heat-conducting member 1200 according to the embodiment may include the second recess R2 positioned to correspond to the first recess R1. Accordingly, a limit on the thickness of the circuit unit 1500 disposed in the first, recess R1 may be addressed. The second recess R2 may be disposed to be spaced apart from the region which comes into contact with the thermoelectric element 1300 like the first recess R1.

For example, the thickness of the circuit unit 1500 may be greater than or equal to a height of the first recess R1. In an embodiment, the height of the recess may be a length between a lower surface of the recess and an upper surface of the recess. An upper surface of the first recess may be an upper surface of the first heat-conducting member, and an upper surface of the second recess may be a lower surface of the second heat-conducting member. Further, the thickness of the circuit unit 1500 may be smaller than the sum of the height of the first recess R1 and the height of the second recess R2. Accordingly, compatibility of the thermoelectric module according to the embodiment with respect to a change in size of the circuit unit 1500 may be improved.

Furthermore, the second heat-conducting member 1200 may include a second edge groove G2. The second edge groove G2 may be positioned on a second surface M2 of the second heat-conducting member 1200 facing the first heat-conducting member 1100. The sealing member 1400 may be disposed in the second edge groove G2. Further, the second edge groove G2 may be disposed to face the first edge groove G1. In addition, the second edge groove G2 may be positioned to at least partially overlap the first edge groove G1 in the first direction (the X-axis direction). Accordingly, moisture resistance of the thermoelectric module may be improved by the sealing member 1400 applied between the first edge groove G2 and the second edge groove G2.

Likewise, the second edge groove G2 may be disposed outside the thermoelectric element 1300 and the second recess R2. In an embodiment, the second edge groove G2 may be disposed along an edge of the second surface M2 of the second heat-conducting member 1200. Further, the second edge groove G2 may have a closed-loop shape in the YZ plane perpendicular to the first direction. Accordingly, the thermoelectric element 1300, the circuit unit 1500, the first recess R1, and the second recess R2 may be surrounded by the sealing member 1400.

Further, the thermoelectric element 1300 and the circuit unit 1500 may be shielded by the first heat-conducting member 1100 and the second heat-conducting member 1200 as well as the sealing member 1400. For example, the first heat-conducting member 1100 may be positioned under the thermoelectric element 1300, the second heat-conducting member 1200 may be positioned above the thermoelectric element 1400, and the sealing member 1400 may be positioned outside the thermoelectric element 1300. That is, the thermoelectric element 1300 may be positioned in the inner region formed by the first heat-conducting member 1100, the second heat-conducting member 1200, and the sealing member 1400. Accordingly, the moisture resistance of the thermoelectric module according to the embodiment may be improved.

The thermoelectric element 1300 may be disposed between the first heat-conducting member 1100 and the second heat-conducting member 1200. Further, there may be a plurality of thermoelectric elements 1300, and the plurality of thermoelectric elements 1300 may be electrically connected to each other. For example, the plurality of thermoelectric elements 1300 may be connected to each other in series or in parallel. To this end, connection boards BD for electrical connection between the thermoelectric elements may be additionally disposed at one sides of the plurality of thermoelectric elements 1300.

Further, in the thermoelectric element 1300, one of a lower substrate (or a first substrate) and an upper substrate (or a second substrate) may come into contact with the first heat-conducting member 1100, and the other may come into contact with the second heat-conducting member 1200. Accordingly, the lower substrate (for example, the low-temperature portion) of the thermoelectric element may receive heat conducted to the first heat-conducting member 1100 by the first fluid in the first pipe P1. Further, the upper substrate (for example, the high-temperature portion) of the thermoelectric element may receive heat conducted to the second heat-conducting member 1200 by the second fluid of the second pipe P2. Accordingly, the thermoelectric element 1300 may generate power from a temperature difference generated between the lower substrate and the upper substrate. In this case, the generated power may be supplied to a battery unit (not shown), or may be applied to drive a separate power component or system. Detailed descriptions of the thermoelectric element 1300 will be described below.

The sealing member 1400 may be disposed along an edge of the first heat-conducting member 1100 or the second heat-conducting member 1200 outside the thermoelectric element 1300. Further, the sealing member 1400 may be disposed between the first heat-conducting member 1100 and the second heat-conducting member 1200. For example, the sealing member 1400 may be spaced apart from the edge of the first heat-conducting member 1100 or the second heat-conducting member 1200 by a predetermined distance to surround the thermoelectric element 1300. That is, the sealing member 1400 may be positioned outside the thermoelectric element 1300. Further, in an embodiment, the sealing member 1400 may be positioned at the outermost side between the first heat-conducting member 1100 and the second heat-conducting member 1200. The sealing member 1400 may have a closed-loop structure with respect to the YZ plane perpendicular to the first direction. Accordingly, external moisture and foreign substances may be prevented from moving to the thermoelectric element in the sealing member 1400. That is, the performance and reliability of the thermoelectric module according to the embodiment may be improved.

Further, the sealing member 1400 may be disposed outside the second recess R2, the first recess R1, and the circuit unit 1500. Accordingly, the sealing member 1400 may be disposed to surround the second recess R2, the first recess R1, and the circuit unit 1500.

More specifically, the sealing member 1400 may surround the thermoelectric element 1300 disposed between the first heat-conducting member 1100 and the second heat-conducting member 1200 on the YZ plane. In other words, the sealing member 1400 may be positioned in a region around the thermoelectric element 1300 on the YZ plane. Accordingly, the thermoelectric element 1300 may overlap the sealing member 1400 in the second direction (the Y-axis direction) or the third direction (the Z-axis direction). Furthermore, since the sealing member 1400 is positioned in the first edge groove G1 and the second edge groove G2, a length of the sealing member 1400 in the first direction may be greater than a length of the thermoelectric element 1300 in the first direction.

Accordingly, the first heat-conducting member 1100 may be positioned under the thermoelectric element 1300, the second heat-conducting member 1200 may be positioned above the thermoelectric element 1400, and the sealing member 1400 may be positioned outside the thermoelectric element 1300. That is, the thermoelectric element 1300 may be positioned in the inner region formed by the first heat-conducting member 1100, the second heat-conducting member 1200, and the sealing member 1400.

Further, the sealing member 1400 may be disposed outside the first recess R1 and the circuit unit 1500 disposed in the first recess R1 to surround the first recess R1 and the circuit unit 1500 as well as the thermoelectric element 1300. In this case, an edge or outer portion of the circuit unit 1500 may be surrounded by the first heat-conducting member 1100, the second heat-conducting member 1200, and the sealing member 1400.

Furthermore, as a modified example, a hole which connects the inner region formed by the first heat-conducting member 1100, the second heat-conducting member 1200, and the sealing member 1400 and the outside may be formed, and an additional member may be further disposed in the hole.

The circuit unit 1500 may be electrically connected to the plurality of thermoelectric elements 1300. The circuit unit 1500 may include a driver DR for optimizing power generation performance due to a temperature difference in the plurality of thermoelectric elements 1300, and a switching unit SW for switching an electrical connection between the thermoelectric elements 1300 and a resistor.

For example, in the thermoelectric element 1300, an output voltage may be determined according to the temperature difference between the low-temperature portion and the high-temperature portion, that is, the temperature difference between the first substrate and the second substrate, and internal resistance. Further, maximum power may differ depending on the output voltage, internal resistance, and load. Accordingly, the driver DR may transfer the maximum power by setting the load to correspond to the internal resistance of the thermoelectric element. For example, the driver DR may transfer the maximum power to the load by adjusting the load to be the same as the internal resistance of the thermoelectric element. Further, the circuit unit 1500 may be electrically connected to an external element (for example, a battery) to be described below. For example, both ends of the internal resistor and the external element may be electrically connected to each other. The circuit unit 1500 according to the embodiment may come into contact with the first heat-conducting member 1100. Since transfer of maximum power becomes difficult when resistance of the circuit unit 1500 increases according to the temperature, the circuit unit 1500 may be positioned in the first recess of the first heat-conducting member 1100 to maintain a state in which the temperature is relatively low. Further, since the circuit unit 1500 is positioned in the first recess R1, an electrical distance between the thermoelectric element 1300 and the circuit unit 1500 is reduced, and thus the resistance on a line added to the internal resistance of the thermoelectric element may be minimized. Accordingly, the thermoelectric element according to the embodiment may provide high-efficiency power transfer, and may minimize heat generation according to driving of the circuit unit 1500 in the first heat-conducting member 1100 of the low-temperature portion. Accordingly, the reliability of the circuit unit 1500 may be improved.

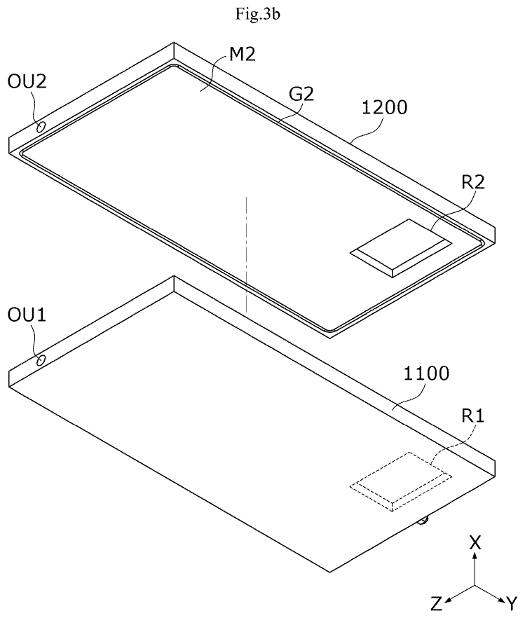

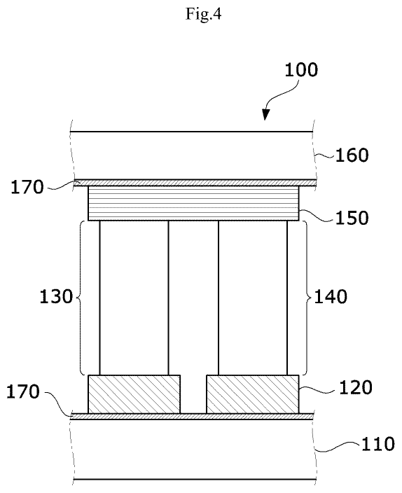

FIG. 4 is a cross-sectional view of the thermoelectric element included in the thermoelectric module according to the embodiment of the present invention, and FIG. 5 is a conceptual diagram of the thermoelectric element included in the thermoelectric module according to the embodiment of the present invention.

Referring to FIGS. 4 and 5, a thermoelectric element 100 includes a lower substrate 110, lower electrodes 120, a P-type thermoelectric leg 130, an N-type thermoelectric leg 140, an upper electrode 150, and an upper substrate 160.

The lower electrodes 120 are disposed between the lower substrate 110 and lower bottom surfaces of the P-type thermoelectric leg 130 and the N-type thermoelectric leg 140, and the upper electrode 150 is disposed between the upper substrate 160 and upper bottom surfaces of the P-type thermoelectric leg 130 and the N-type thermoelectric leg 140. Accordingly, a plurality of P-type thermoelectric legs 130 and a plurality of N-type thermoelectric legs 140 are electrically connected by the lower electrodes 120 and the upper electrodes 150. One pair of the P-type thermoelectric leg 130 and the N-type thermoelectric leg 140 which are disposed between the lower electrodes 120 and the upper electrode 150 and electrically connected to each other may form a unit cell.

For example, when a voltage is applied to the lower electrodes 120 and the upper electrodes 150 through lead lines 181 and 182, a substrate through which current flows from the P-type thermoelectric legs 130 to the N-type thermoelectric legs 140 due to the Peltier effect may absorb heat and act as a cooling unit, and a substrate through which current flows from the N-type thermoelectric legs 140 to the P-type thermoelectric legs 130 may be heated and act as a heating unit. Alternatively, when a temperature difference between the lower electrode 120 and the upper electrode 150 is applied, electric charges in the P-type thermoelectric leg 130 and the N-type thermoelectric leg 140 may move due to the Seebeck effect, and electricity may be generated

Here, the P-type thermoelectric leg 130 and the N-type thermoelectric leg 140 may be bismuth-telluride (Bi—Te)-based thermoelectric legs including bismuth (Bi) and tellurium (Te) as main raw materials. The P-type thermoelectric leg 130 may be a bismuth-telluride (Bi—Te)-based thermoelectric leg including at least one of antimony (Sb), nickel (Ni), aluminum (Al), copper (Cu), silver (Ag), lead (Pb), boron (B), gallium (Ga), tellurium (Te), bismuth (Bi), and indium (In). For example, the P-type thermoelectric leg 130 may include Bi—Sb—Te, which is a main raw material, in an amount of 99 to 99.999 wt %, and may include at least one of nickel (Ni), aluminum (Al), copper (Cu), silver (Ag), lead (Ph), boron (B), gallium (Ga), and indium (In) in an amount of 0.001 to 1 wt % based on 100 wt % of the total weight. The N-type thermoelectric leg 140 may be a bismuth-telluride (Bi—Te)-based thermoelectric leg including at least one of selenium (Se), nickel (Ni), aluminum (Al), copper (Cu), silver (Ag), lead (Pb), boron (B), gallium (Ga), tellurium (Te), bismuth (Bi), and indium (In). For example, the N-type thermoelectric leg 140 may include Bi—Se—Te, which is a main raw material, in an amount of 99 to 99.999 wt %, and may include at least one of nickel (Ni), aluminum (Al), copper (Cu), silver (Ag), lead (Pb), boron (B), gallium (Ga), and indium (In) in an amount of 0.001 to 1 wt % based on 100 wt % of the total weight.

The P-type thermoelectric leg 130 and the N-type thermoelectric leg 140 may be formed in a bulk type or a stacked type. Generally, the bulk type P-type thermoelectric leg 130 or the bulk type N-type thermoelectric leg 140 may be acquired through a process of manufacturing an ingot by heat-treating a thermoelectric material, acquiring powder for thermoelectric legs by pulverizing and sieving the ingot, sintering the powder, and then cutting a sintered object. In this case, the P-type thermoelectric leg 130 and the N-type thermoelectric leg 140 may be polycrystalline thermoelectric legs. Like the above, when the P-type thermoelectric leg 130 and the N-type thermoelectric leg 140 are polycrystalline thermoelectric legs, the strength of the P-type thermoelectric leg 130 and the N-type thermoelectric leg 140 may be improved. The stacked type P-type thermoelectric leg 130 or the stacked type N-type thermoelectric leg 140 may be acquired through a process of forming a unit member by applying a paste including a thermoelectric material on a sheet-shaped base material, and then stacking and cutting the unit member.

In this case, one pair of the P-type thermoelectric leg 130 and the N-type thermoelectric leg 140 may have the same shape and volume or may have different shapes and volumes. For example, since electrical conduction characteristics of the P-type thermoelectric leg 130 and the N-type thermoelectric leg 140 are different, a height or cross-sectional area of the N-type thermoelectric leg 140 may be formed differently from a height or cross-sectional area of the P-type thermoelectric leg 130.

In this case, the P-type thermoelectric leg 130 or the N-type thermoelectric leg 140 may have a cylindrical shape, a polygonal columnar shape, an elliptical columnar shape, or the like.

The performance of the thermoelectric element according to the embodiment of the present invention may be expressed as a thermoelectric figure of merit (ZT). The thermoelectric figure of merit (ZT) may be expressed as in Equation 1.

ZT=α²·σT/k [Equation 1]

Here, α denotes the Seebeck coefficient [VAC], σ denotes electrical conductivity [S/m], and α²σ denotes a power factor (W/mK²]). Further, T denotes temperature, and k denotes thermal conductivity [W/mK]. k may be expressed as a·cp·ρ, wherein a denotes thermal diffusivity [cm²/S], cp denotes specific heat [J/gK], and ρ denotes density [g/cm³].

In order to acquire the thermoelectric figure of merit of the thermoelectric element, a Z value (V/K) may be measured using a Z meter, and the thermoelectric figure of merit (ZT) may be calculated using the measured Z value.

Here, each of the lower electrodes 120 disposed between the lower substrate 110 and the P-type thermoelectric leg 130 and the N-type thermoelectric leg 140 and the upper electrode 150 disposed between the upper substrate 160 and the P-type thermoelectric leg 130 and the N-type thermoelectric leg 140 may include at least one of copper (Cu), silver (Ag), aluminum (Al), and nickel (Ni), and may have a thickness of 0.01 mm to 0.3 mm. When the thickness of the lower electrode 120 or the upper electrode 150 is smaller than 0.01 mm, the function as an electrode may be deteriorated and the electrical conduction performance may be lowered, and when the thickness of the lower electrode 120 or the upper electrode 150 exceeds 0.3 mm, conduction efficiency may be lowered due to an increase in resistance.

Further, the lower substrate 110 and the upper substrate 160 opposite each other may be metal substrates, and each thickness thereof may be 0.1 mm to 1.5 mm. When the thickness of the metal substrate is smaller than 0.1 mm or exceeds 1.5 mm, since heat dissipation characteristics or thermal conductivity may be excessively high, the reliability of the thermoelectric element may be deteriorated. Further, when the lower substrate 110 and the upper substrate 160 are metal substrates, insulating layers 170 may be further formed between the lower substrate 110 and the lower electrode 120 and between the upper substrate 160 and the upper electrode 150. The insulating layer 170 may include a material having a thermal conductivity of 1 to 20 W/mK. In this case, the insulating layer 170 may be a resin composition including at least one of an epoxy resin and a silicone resin and an inorganic material, a layer formed of a silicone composite including silicone and an inorganic material, or an aluminum oxide layer. Here, the inorganic material may be at least one of oxides, nitrides, and carbides of aluminum, boron, silicon, and the like.

In this case, the lower substrate 110 and the upper substrate 160 may be formed to have different sizes. For example, a volume, thickness, or area of one of the lower substrate 110 and the upper substrate 160 may be formed to be larger than a volume, thickness, or area of the other. Here, the thickness may be a thickness in a direction from the lower substrate 110 to the upper substrate 160, and the area may be an area in a direction perpendicular to the direction from the substrate 110 to the upper substrate 160. Accordingly, it is possible to improve the heat absorption performance or heat dissipation performance of the thermoelectric element. Preferably, the volume, thickness, or area of the lower substrate 110 may be formed to be larger than the volume, thickness, or area of the upper substrate 160. In this case, when the lower substrate 110 is disposed in a high-temperature region for the Seebeck effect, the lower substrate 110 is applied as a heating region for the Peltier effect, or a sealing member for protecting the thermoelectric element to be described below from an external environment is disposed on the lower substrate 110, at least one of the volume, thickness, and area of the lower substrate 110 may be larger than that of the upper substrate 160. In this case, the area of the lower substrate 110 may be formed in a range of 1.2 to 5 times the area of the upper substrate 160. When the area of the lower substrate 110 is formed to be less than 12 times the area of the upper substrate 160, the influence on improvement of heat transfer efficiency is not high, and the area of the lower substrate 110 exceeds 5 times the area of the upper substrate 160, the heat transfer efficiency may significantly deteriorate, and it may be difficult to maintain a basic shape of the thermoelectric device.

Further, a heat dissipation pattern, for example, a concavo-convex pattern may be formed on the surface of at least one of the lower substrate 110 and the upper substrate 160. Accordingly, the heat dissipation performance of the thermoelectric element may be improved. When the concavo-convex pattern is formed on the surface which comes into contact with the P-type thermoelectric leg 130 or the N-type thermoelectric leg 140, bonding characteristics between the thermoelectric leg and the substrate may also be improved. The thermoelectric element 100 includes the lower substrate 110, the lower electrodes 120, the P-type thermoelectric leg 130, the N-type thermoelectric leg 140, the upper electrode 150, and the upper substrate 160.

Although not shown in the drawings, a sealing member may be further disposed between the lower substrate 110 and the upper substrate 160. The sealing member may be disposed on side surfaces of the lower electrodes 120, the P-type thermoelectric legs 130, the N-type thermoelectric legs 140, and the upper electrodes 150 between the lower substrate 110 and the upper substrate 160. Accordingly, the lower electrodes 120, the P-type thermoelectric legs 130, the N-type thermoelectric legs 140, and the upper electrodes 150 may be sealed from external moisture, heat, contamination, and the like.

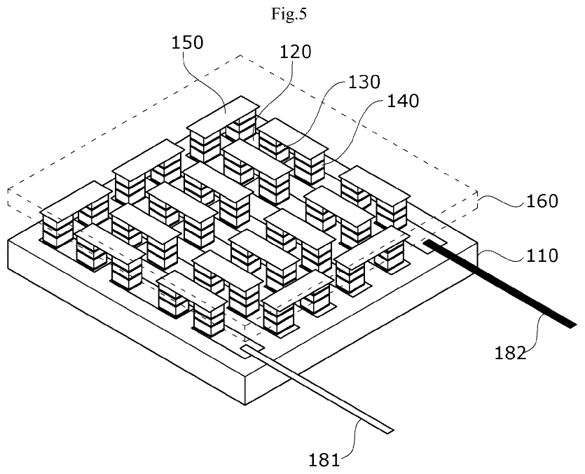

FIG. 6 is an exploded perspective view of the thermoelectric element according to the embodiment of the present invention.

Referring to FIG. 6, the thermoelectric element 1300 according to the embodiment of the present invention includes a first substrate 1310, a first insulating layer 1320 disposed on the first substrate 1310, a plurality of first electrodes 1330 disposed on the first insulating layer 1320, a plurality of P-type thermoelectric legs 1340 and a plurality of N-type thermoelectric legs 1350 disposed on the plurality of first electrodes 1330, a plurality of second electrodes 1360 disposed on the plurality of P-type thermoelectric legs 1340 and the plurality of N-type thermoelectric legs 1350, a second insulating layer 1370 disposed on the plurality of second electrodes 1360, and a second substrate 1380 disposed on the insulating layer 1370.

Further, although not shown, a cover member (not shown) may be further disposed to surround the plurality of first electrodes 1330, the plurality of P-type thermoelectric legs 1340, the plurality of N-type thermoelectric legs 1350, the plurality of second electrodes 1360, and the second insulating layer 1370.

Here, the first electrodes 1330, the P-type thermoelectric legs 1340, the N-type thermoelectric legs 1350, and the second electrodes 1360 may correspond to the lower electrodes 120, and the P-type thermoelectric legs 130, the N-type thermoelectric legs 140, and the upper electrodes 150 described in FIGS. 4 and 5, respectively. Further, since the first substrate 1310 corresponds to the lower substrate 110, the second substrate 1380 corresponds to the upper substrate 160, and the first insulating layer 1320 and the second insulating layer 1370 correspond to the insulating layers 170, the contents described in FIGS. 4 and 5 may be applied to the corresponding component in the same or similar manner.

In addition, at least one of the first substrate 1310 and the second substrate 1380 may be a metal substrate. For example, at least one of the first substrate 1310 and the second substrate 1380 may be formed of at least one of aluminum, an aluminum alloy, copper, and a copper alloy. The first substrate 1310 and the second substrate 1380 may be formed of different materials. For example, among the first substrate 1310 and the second substrate 1380, a substrate which requires more withstand voltage performance may be formed as an aluminum substrate, and a substrate which requires more heat conduction performance may be formed as a copper substrate.

In the present specification, the withstand voltage performance may refer to a characteristic which is maintained without dielectric breakdown for a predetermined period under a predetermined voltage and a predetermined current. For example, when maintained for 10 seconds without dielectric breakdown under a voltage of alternating current (AC) 2.5 kV and a current of 1 mA, the withstand voltage may be 2.5 kV.

Further, since a power source is connected to the electrodes disposed at the low-temperature portion side of the thermoelectric element 1300, higher withstand voltage performance may be required at the low-temperature portion side than at the high-temperature portion side. On the other hand, when the thermoelectric element 1300 is driven, the high-temperature portion side of the thermoelectric element 1300 may be exposed to a high temperature, for example, approximately 180° C. or more, and since the electrodes, the insulating layer, and the substrate have different thermal expansion coefficients, delamination between the electrodes, the insulating layer, and the substrate may become a problem. Accordingly, higher thermal shock mitigation performance may be required at the high-temperature portion side of the thermoelectric element 1300 than at the low-temperature portion side of the thermoelectric element 1300. Accordingly, a structure at the high-temperature portion side and a structure at the low-temperature portion side may be different.

Hereinafter, connection of electrode connection parts 1390 and 1391 to the first electrodes 1330 disposed on the first substrate 1310 will be described with reference to FIG. 6.

As described above, the first insulating layer 1320 may be disposed on the first substrate 1310, and the plurality of first electrodes 1330 may be disposed on the first insulating layer 1320.

Further, each of the electrode connection parts 1390 and 1391 may include a first connection unit 1392 and a second connection unit 1393 having different polarities. For example, when a (−) terminal is connected to the first connection unit 1392, a (+) terminal may be connected to the second connection unit 1393. For example, the first connection unit 1392 of the electrode connection parts 1390 and 1391 may connect one of the plurality of first electrodes 1330 to the (−) terminal, and the second connection unit 1393 of the electrode connection parts 1390 and 1391 may connect another one of the plurality of first electrodes 1330 to the (+) terminal. Accordingly, the positions of the electrode connection parts 1390 and 1391 may affect the insulation resistance of the thermoelectric element 1300. Further, the first connection unit 1392 and the second connection unit 1393 are formed in plural, and thus may be connected to wires or the like when the thermoelectric elements are connected in series or in parallel. Accordingly, an electrical connection relationship (for example, series or parallel) of the thermoelectric module may be easily changed. The insulation resistance refers to electrical resistance exhibited by an insulator when a predetermined voltage is applied, and the thermoelectric element 1300 should satisfy a predetermined insulation resistance. For example, the thermoelectric element 1300 should satisfy a requirement of having an insulation resistance of 500 MΩ or more when a direct current (DC) voltage of 500 V is applied.

According to the embodiment, the electrode connection parts 1390 and 1391 may extend to one side on the first substrate 1310. Further, the electrode connection parts 1390 and 1391 may be drawn out to the outside of a sealing member (not shown) to surround the first insulating layer 1320, the plurality of first electrodes 1330, the plurality of P-type thermoelectric legs 1340, the plurality of N-type thermoelectric legs 1350, the plurality of second electrodes 1360, and the second insulating layer 1370 disposed between the first substrate 1310 and the second substrate 1380.

Further, each of the first connection unit 1392 and the second connection unit 1393 may be a connector into which a wire is detachably inserted. As described above, each of the electrode connection parts 1390 and 1391, the first connection unit 1392, and the second connection unit 1393 may be disposed outside or inside the sealing member. When each of the electrode connection parts 1390 and 1391, the first connection unit 1392, and the second connection unit 1393 is disposed outside, wire connection is easy, and the possibility of a disconnection between the electrodes and the wires may be minimized. When each of the electrode connection parts 1390 and 1391, the first connection unit 1392, and the second connection unit 1393 is disposed inside, the reliability of the element may be improved.

Further, each of the first connection unit 1392 and the second connection unit 1393 may, be sealed by a resin including silicone. Accordingly, the insulation resistance and the withstand voltage performance of the thermoelectric element may be further improved.

Further, the first insulating layer 1320 is disposed under the plurality of first electrodes 1330 and the electrode connection parts 1390 and 1391 on the first substrate 1310, and may have a larger area than the first electrode 1330 and the electrode connection parts 1390 and 1391. Accordingly, the first electrodes 1330 and the electrode connection parts 1390 and 1391 may overlap the first insulating layer 1320 in the vertical direction (the X-axis direction).

The first insulating layer 1320 may have a larger area than the second insulating layer 1370. Accordingly, a portion of the first insulating layer 1320 may overlap the second insulating layer 1370 in the vertical direction (the X-axis direction).

The second insulating layer 1370 may be disposed between the second electrodes 1360 and the second substrate 1380. An area of the second insulating layer 1370 may be larger than an entire area of the plurality of second electrodes 1360. Accordingly, the plurality of second electrodes 1360 may overlap the second insulating layer 1370 in the vertical direction (the X-axis direction).

Further, the plurality of second electrodes 1360 may be disposed to face the plurality of first electrodes 1330 with the plurality of P-type thermoelectric legs 1340 and the plurality of N-type thermoelectric legs 1350 therebetween. The plurality of first electrodes 1330 and the plurality of second electrodes 1360 may be electrically connected to each other through the plurality of P-type thermoelectric legs 1340 and the plurality of N-type thermoelectric legs 1350. For example, the plurality of first electrodes 1330 and the plurality of second electrodes 1360 may be connected to each other in series.

Further, each of the plurality of second electrodes 1360 may be arranged in the same shape under the second substrate 1380 or the second insulating layer 1370.

Furthermore, the first substrate 1310 may include substrate holes positioned outside the first insulating layer 1320. The substrate holes may include a first substrate hole 1310111 and a second substrate hole 1310h2. The thermoelectric element 1300 or the first substrate 1310 may be coupled to the first heat-conducting member 1100 through the first substrate hole 1310h1 and the second substrate hole 1310h2. Detailed descriptions thereof will be described below.

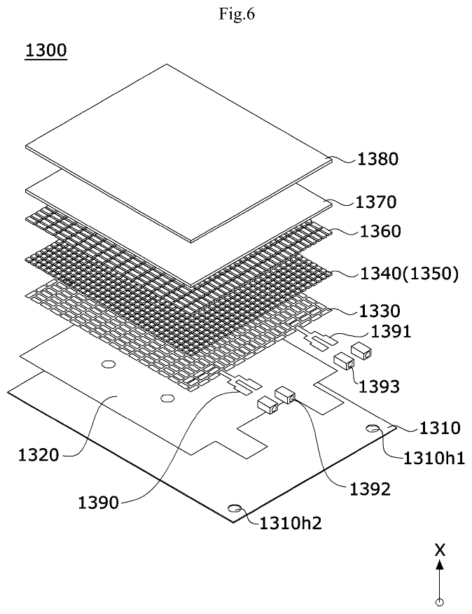

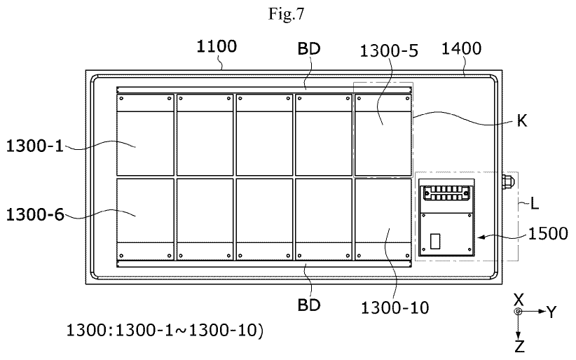

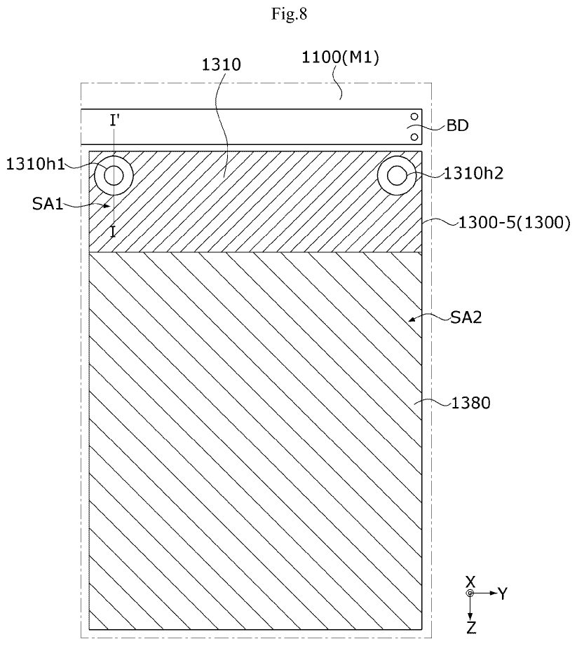

FIG. 7 is a view in which the second heat-conducting member is removed from the thermoelectric module according to the embodiment of the present invention, FIG. 8 is an enlarged view of portion K in FIG. 7, and FIG. 9 is a cross-sectional view taken along line I-I′ in FIG. 8.

Referring to FIGS. 7 to 9, in the thermoelectric element 1300 according to the embodiment, the first substrate 1310 may include a first region SA1 not overlapping the second substrate 1380 in the first direction (the X-axis direction) and a second region SA2 overlapping the second substrate 1380 in the first direction (the X-axis direction). In this case, as described above, the first direction may correspond to the direction from the first pipe P1 to the second pipe P2, the direction from the first heat-conducting member to the second heat-conducting member, or the direction from the first substrate 1310 to the second substrate 1380.

The first region SA1 may not overlap the first electrodes 1330, the plurality of P-type thermoelectric legs 1340, the plurality of N-type thermoelectric legs 1350, the second electrodes 1360, and the second insulating layer 1370 in the first direction (the X-axis direction).

The first substrate hole 1310111 and the second substrate hole 1310h2 according to the embodiment may be positioned in the first region SA. Further, coupling members SC may be seated in the first substrate hole 1310h1 and the second substrate hole 1310h2.

Further, the first heat-conducting member 1100 may include coupling grooves 1100g at positions corresponding to the first substrate hole 1310h1 and the second substrate hole 1310h2 of the first substrate 1310. The coupling grooves 1100g may overlap the above-described substrate holes in the first direction (the X-axis direction). Further, the coupling members SC may be seated in the coupling grooves 1100g.

In addition, each of side surfaces f1 of the coupling grooves 1100g may have a pattern for coupling with the coupling member SC and facilitating heat conduction. In addition, bottom surfaces f2 of the coupling grooves 1100g may have various patterns like the side surfaces f1.

That is, the coupling members SC may pass through the substrate holes 1310h1 and 1310h2 and may pass through at least portion of the first heat-conducting member 1100. The coupling member SC may be formed with a screw thread and a root on an outer surface thereof. Further, the substrate hole and the coupling groove 1100g have shapes corresponding to the outer surface of the coupling member SC, and thus may be fastened to the coupling member SC.

That is, the coupling members SC may come into contact with the first heat-conducting member 1100 and may be spaced apart from the second heat-conducting member. According to this configuration, since the thermoelectric element 1300 is coupled to the first heat-conducting member 1100, movement of the thermoelectric element 1300 may be suppressed. Accordingly, as the thermoelectric element 1300 moves, a phenomenon in which the heat is not efficiently transferred from the above-described first pipe and second pipe may be suppressed. Further, since the coupling members SC are fastened to the first heat-conducting member 1100 having a relatively low temperature, the occurrence of structural deformation such as distortion or the like due to heat may be suppressed compared to the case in which the coupling members SC are fastened to the second heat-conducting member having a relatively high temperature. Accordingly, the reliability of the thermoelectric module may be improved. Further, when fastening is performed to the second heat-conducting member having a relatively high-temperature through the coupling members SC, a warping phenomenon due to the high temperature may occur, and power generation performance deterioration may occur due to heat loss. Accordingly, since the thermoelectric module according to the embodiment prevents the above-described warping phenomenon and performance deterioration, improved reliability and power generation performance may be provided.

Further, the coupling grooves 1100g overlap the substrate holes in the first direction (the X-axis direction), and thus may also overlap the first region SA1 of the first substrate 1310 in the first direction (the X-axis direction). The coupling members SC may also overlap the first region SA1.

Furthermore, a bonding member may be positioned between the second substrate 1380 and the second heat-conducting member. Accordingly, as described above, the second substrate 1380 and the second heat-conducting member may be coupled to each other. The bonding member may be formed of a heat-conducting material.

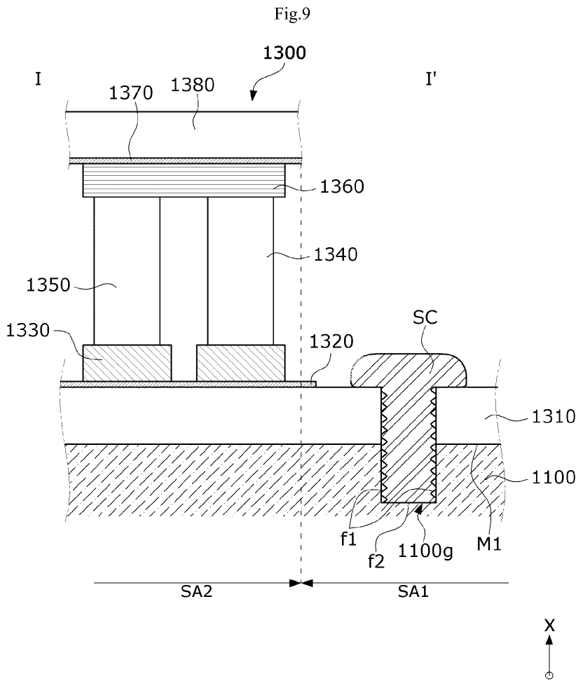

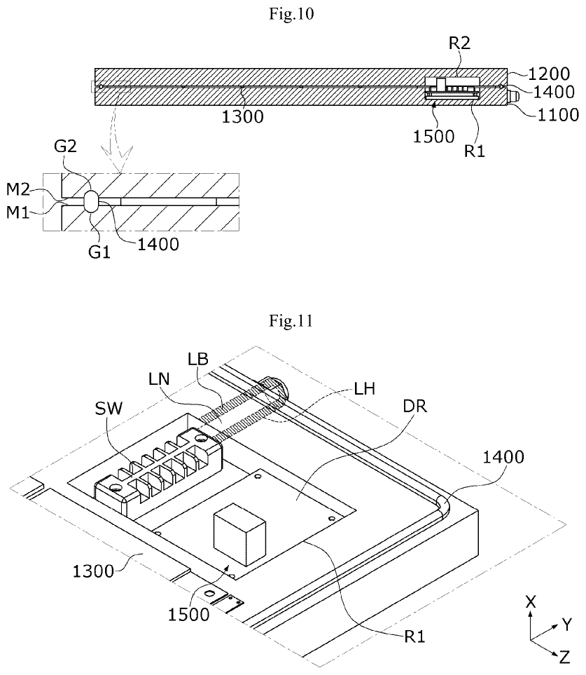

FIG. 10 is a cross-sectional view taken along line J-J′ in FIG. 1, and FIG. 11 is an enlarged view of portion L in FIG. 7.

Referring to FIGS. 10 and 11, the thermoelectric element 1300 may be disposed on the first heat-conducting member. The thermoelectric element 1300 may include a plurality of first to tenth thermoelectric elements 1300-1 to 1300-10. That is, the number of thermoelectric elements 1300 may be ten, but is not limited to this number. That is, it should be understood that the number of thermoelectric elements 1300 may be set in consideration of power generation performance or the like.

The sealing member 1400 according to the embodiment may be positioned between the first heat-conducting member 1100 and the second heat-conducting member 1200. Specifically, the sealing member 1400 may be positioned between the first edge groove G1 in the first surface M1 of the first heat-conducting member 1100 and the second edge groove G2 in the second surface M2 of the second heat-conducting member 1200. In this case, the first edge groove G1 and the second edge groove G2 may be positioned to correspond to each other. That is, the first edge groove G1 and the second edge groove G2 may overlap each other in the first direction (the X-axis direction). Accordingly, the sealing member 1400 may prevent the penetration of external moisture, foreign substances, and the like into the circuit unit 1500 or the thermoelectric element 1300 positioned inside the sealing member 1400.

That is, the plurality of thermoelectric elements 1300-1 to 1300-10 may be positioned inside the sealing member 1400. Further, a blocking member (not shown) may be additionally disposed between the sealing member 1400 and the plurality of thermoelectric elements 1300-1 to 1300-10. Accordingly, the plurality of thermoelectric elements 1300-1 to 1300-10, the blocking member (not shown) or the circuit unit 1500, and the sealing member 1400 may be sequentially positioned from the inside to the outside in a region between the first heat-conducting member 1100 and the second heat-conducting member 1200.

Further, the thermoelectric elements 1300-1 to 1300-5 disposed side by side at one side among the plurality of thermoelectric elements may be electrically connected to an upper board BD. In addition, the thermoelectric elements 1300-6 to 1300-10 disposed side by side at one side among the plurality of thermoelectric elements may be electrically connected to a lower board BD. Connection through wires between the plurality of thermoelectric elements may be easily made through the boards BD, and a phenomenon in which an electrical problem such as a short circuit or the like due to an electrical connection between wires connected to adjacent thermoelectric elements occurs may be prevented.

Furthermore, the circuit unit 1500 may be disposed inside the sealing member 1400 extending along an edge of the thermoelectric element 1300 and electrically connected to the plurality of thermoelectric elements 1300. The circuit unit 1500 may include a driver for optimizing power generation performance due to a temperature difference in the plurality of thermoelectric elements 1300. Further, as described above, the circuit unit 1500 may adjust the magnitude of a variable resistor in electrical connection between the thermoelectric element 1300 and the variable resistor. In an embodiment, the circuit unit 1500 may include a variable resistor.

More specifically, the circuit unit 1500 may be electrically connected to the thermoelectric element 1300 to adjust the variable resistor in response to the internal resistor according to a temperature difference (for example, a temperature difference between the first substrate and the second substrate, a temperature difference between the first fluid and the second fluid, or the like). Accordingly, a voltage for maximum power transfer may be applied to both ends of the internal resistor. Accordingly, power generation according to the temperature difference may be performed.

Further, a connection line to be described below may be connected to both ends of the internal resistor, the connection line may be electrically connected to an external battery or the like, and the battery may be charged with a voltage corresponding to both ends of the internal resistor. The thermoelectric module according to the embodiment may or may not include a battery. In the present specification, it is described that the thermoelectric module does not include a battery.

Furthermore, a box for protecting wires or the like may be added to the circuit unit 1500. The wires of the circuit unit may be disposed in the box to be additionally protected against moisture and the like.

Further, the circuit unit 1500 according to the embodiment may come into contact with the first heat-conducting member. According to this configuration, the circuit unit 1500 may maintain a relatively low temperature, and thus may minimize the heat generated according to driving. That is, reliability may be improved.

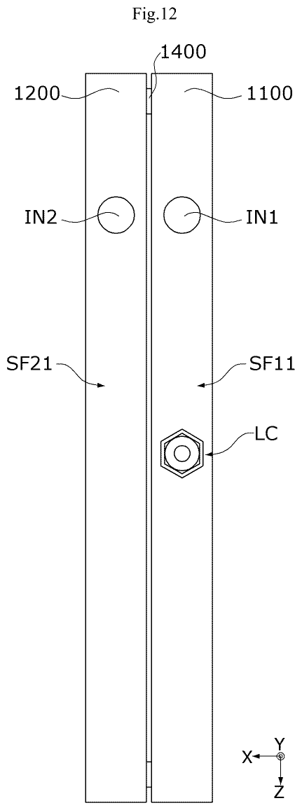

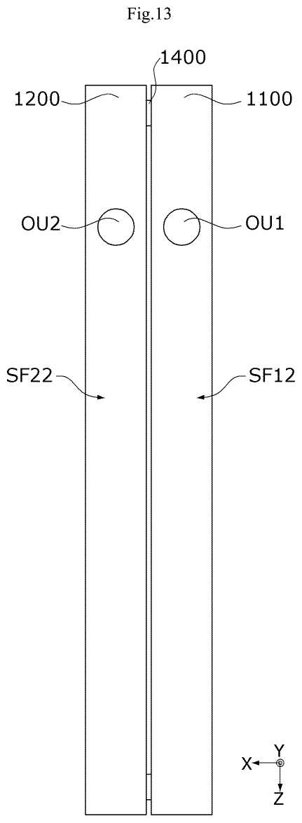

FIG. 12 is a side view of the thermoelectric module according to the embodiment, and FIG. 13 is another side view of the thermoelectric module according to the embodiment.

Referring to FIGS. 12 and 13, the above-described first inlet IN1 may be positioned on a 1-1 side surface SF11 of the first heat-conducting member 1100 in the thermoelectric module according to the embodiment. Further, the above-described second inlet IN2 may be positioned on a 2-1 side surface SF11 of the second heat-conducting member 1200. The first inlet IN1 and the second inlet IN2 may be positioned to correspond to each other. In an embodiment, the first inlet IN1 and the second inlet IN2 may be positioned to overlap each other in the first direction (the X-axis direction).

Furthermore, the first heat-conducting member 1100 may include a 1-2 side surface SF12 corresponding to or opposite the 1-1 side surface SF11. Further, the second heat-conducting member 1200 may include a 2-2 side surface ST22 corresponding to or opposite the 2-1 side surface SF21.

In an embodiment, the first outlet OU1 may be positioned on the 1-2 side surface SF12 and the second outlet OU2 may be positioned on the 2-2 side surface SF22. The first outlet OU1 and the second outlet OU2 may be positioned to correspond to each other. In an embodiment, the first outlet OU1 and the second outlet OU2 may be positioned to overlap each other in the first direction (the X-axis direction).

Further, as described above, the first pipe which connects the first inlet IN1 and the first outlet OU1 and the second pipe which connects the second inlet IN2 and the second outlet OU2 may also be positioned to correspond to each other. Accordingly, the temperature difference between the first fluid in the first pipe and the second fluid in the second pipe may be uniformly maintained as much as possible according to the corresponding positions between the first pipe and the second pipe. Accordingly, power generation performance may be improved.

In addition, a wire connection part LC for electrical connection to the circuit unit may be positioned in the 1-1 side surface ST11. The circuit unit seated in the first heat-conducting member 1100 may be electrically connected to an external element through the wire connection part LC.

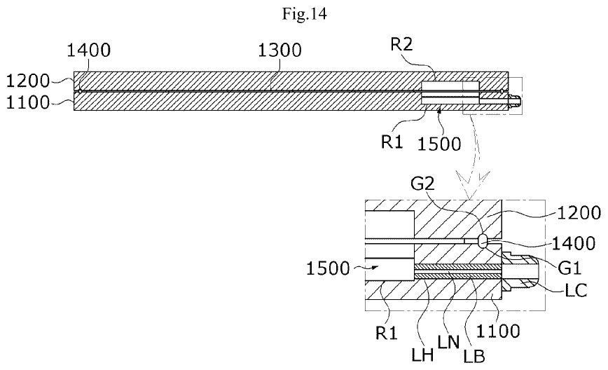

FIG. 14 is a cross-sectional view taken along line M-M′ in FIG. 11.

Referring to FIG. 14, in the thermoelectric module according to the embodiment, the first heat-conducting member 1100 may include a wire hole LH passing through from the outer surface of the first heat-conducting member 1100 (the above-described 1-1 side surface SF11) to the first recess R1. Further, the thermoelectric module may include a connection line LN electrically connected to the circuit unit 1500 and disposed in the wire hole LH, and a protective member LB surrounding the connection line LN in the wire hole LH. That is, since the connection line LN and the protective member LB are disposed in the wire hole LH and the protective member LB is disposed to surround the connection line LN, the wire hole LH may be sealed by the connection line LN and the protective member LB.

Since the connection line LN may be positioned in the wire hole LH, one end of the connection line LN may be electrically connected to an element outside the first heat-conducting member 1100, and the other end of the connection line LN may be electrically connected to the circuit unit 1500.

Further, the protective member LB may be formed of an insulating material. For example; the protective member LB may be formed of epoxy or the like. Further, the protective member LB may be applied in the wire hole LH, and may cover the connection line LN. According to this configuration, external moisture and foreign substances may be prevented from moving into the wire hole LH. That is, the performance and reliability of the thermoelectric module according to the embodiment may be improved.

Further, since the circuit unit 1500 is disposed between the first heat-conducting member 1100 and the second heat-conducting member 1200 through the first recess R1, the electrical distance between the thermoelectric element and the circuit unit 1500 may be minimized. Accordingly, the loss due to the transfer of energy may be minimized. Furthermore, wires for electrical connection between the thermoelectric elements 1300 may be disposed only between the first heat-conducting member 1100 and the second heat-conducting member 1200 and thus may not be exposed to the outside. Accordingly, deterioration of electrical reliability due to moisture or the like may be prevented.

Further, the wire connection part LC may be positioned at a side of an extending direction (for example, the second direction) of the wire hole LH from the outside of the first heat-conducting member 1100. In addition, the wire connection part LC may include an inner hole. Accordingly, the connection line LN disposed in the wire hole LII may be electrically connected to the outside through the wire connection part LC. Further, the above-described protective member LB may be disposed in the hole of the wire connection part LC. Accordingly, the reliability of the device may be improved by protecting the thermoelectric element 1300 or the circuit unit 1500 in the region between the first heat-conducting member 1100 and the second heat-conducting member 1200 from moisture or the like. Furthermore, since the wire connection part surrounds the outside, the connection line LN and the protective member LB in the hole may be pressed by a pressing member which presses toward the inside or the inner hole. According to this configuration, the introduction of foreign substances or the like into the thermoelectric module may be easily blocked by removing empty spaces between the connection line LN, the protective member LB, and the wire connection part LC.

Accordingly, the thermoelectric element according to the embodiment of the present invention may be applied to a device for power generation, a device for cooling, a device for heating, or the like. That is, the above-described contents may be applied to the device for power generation, the device for cooling, or the device for heating including the thermoelectric element, a transportation device such as a vehicle or the like, or various electric devices in the same manner. For example, a power generation system may generate power through heat sources generated from a ship, an automobile, a power plant, geothermal heat, or the like. Further, in the power generation system, a plurality of power generation devices may be arranged to efficiently collect heat sources.

Although the preferable embodiments of the present invention are described above, those skilled in the art may variously modify and change the present invention within the scope and spirit of the present invention disclosed in the following claims.

1. A thermoelectric module comprising:
a first heat-conducting member including a first recess;
a second heat-conducting member disposed to be spaced apart from the first heat-conducting member;
a thermoelectric element disposed between the first heat-conducting member and the second heat-conducting member; and
a circuit unit electrically connected to the thermoelectric element and configured to control resistance,
wherein the circuit unit is disposed in the first recess.

2. The thermoelectric module of claim 1, comprising a connection line passing through the first recess at an outer surface of the first heat-conducting member and electrically connected to the circuit unit.

3. The thermoelectric module of claim 1, comprising a sealing member surrounding the thermoelectric element between the first heat-conducting member and the second heat-conducting member.

4. The thermoelectric module of claim 1, wherein the first heat-conducting member includes a first inlet and a first outlet,
the second heat-conducting member includes a second inlet and a second outlet,
the first inlet and the second inlet are positioned to correspond to each other, and
the first outlet and the second outlet are positioned to correspond to each other.

5. The thermoelectric module of claim 1, wherein the first heat-conducting member includes a first pipe,
the second heat-conducting member includes a second pipe,
the first pipe at least partially overlaps the thermoelectric element in a vertical direction, and
the second pipe at least partially overlaps the thermoelectric element in the vertical direction.

6. The thermoelectric module of claim 1, wherein the thermoelectric element includes a first substrate configured to come into contact with the first heat-conducting member and a second substrate configured to come into contact with the second heat-conducting member.

7. The thermoelectric module of claim 6, wherein the first substrate includes a first region overlapping the second substrate and a second region outside the second substrate,
the second region includes a coupling hole coupled to the first heat-conducting member, and
the thermoelectric module includes a coupling member passing through the coupling hole.

8. The thermoelectric module of claim 7, wherein a bonding member is disposed between the second substrate and the second heat-conducting member.

9. The thermoelectric module of claim 3, wherein the first heat-conducting member includes a first surface facing the second heat-conducting member,
the second heat-conducting member includes a second surface facing the first surface,
the first surface includes a first edge groove disposed along an edge thereof, and
the second surface includes a second edge groove disposed along an edge thereof.

10. The thermoelectric module of claim 9, wherein the first edge groove and the second edge groove overlap in a vertical direction, and
the sealing member is disposed between the first edge groove and the second edge groove.
